(19) United States
(12) Patent Application Publication
(10) Pub. No.: US 2024/0192034 A1
(43) Pub. Date: Jun. 13, 2024

(54) METHOD FOR PRODUCING A SENSOR, AND SENSOR

(71) Applicant: Robert Bosch GmbH, Stuttgart (DE)

(72) Inventor: Maziar Afshar, Tuebingen (DE)

(21) Appl. No.: 18/535,493

(22) Filed: Dec. 11, 2023

(30) Foreign Application Priority Data
Dec. 13, 2022 (DE) 102022213536.9

(51) Int. Cl. G01D 11/24; G01D 11/26; H05K 5/02; H05K 5/03; H05K 5/04

(52) U.S. Cl. CPC G01D 11/245; G01D 11/26; H05K 5/0217; H05K 5/03; H05K 5/04

(57) ABSTRACT

A method for producing a sensor. The method includes: arranging a sensor module in a metallic housing, wherein the housing comprises a housing opening; fixing a metallic cover to or in the housing opening in order to close the housing opening by means of the cover; wherein the fixing comprises an integral connecting of the cover to the housing. A sensor is also described.

### FIELD

The present invention relates to a method for producing a sensor, and to a sensor.

### BACKGROUND INFORMATION

German Patent Application No. DE 10 2020 214 796 A1 describes a method for producing a sensor.

### SUMMARY

An object of the present invention is to provide a design for the efficient production of a sensor.

An object of the present invention is also to provide a sensor.

These objects are achieved by means of features of the present invention. Advantageous embodiments of the present invention are disclosed herein.

According to a first aspect of the present invention, a method for producing a sensor is provided. According to an example embodiment of the present invention, the method comprises the following steps:
arranging a sensor module in a metallic housing, wherein the housing comprises a housing opening,
fixing a metallic cover to or in the housing opening in order to close the housing opening by means of the cover,
wherein the fixing comprises an integral connecting of the cover to the housing.

According to a second aspect of the present invention, a sensor is provided. According to an example embodiment of the present invention, the sensor comprises:
a sensor module which is arranged in a metallic housing, wherein the housing has a housing opening,
wherein the housing opening is closed by means of a metallic cover by the cover being integrally connected to the housing.

The present invention is based on and includes the finding that both a metallic housing and a metallic cover are provided for the sensor. In this case, the sensor module is arranged in the metallic housing and the metallic cover is integrally connected to the housing in order to close the housing opening by means of the cover. By means of the integral connection, a technical advantage is achieved, for example, that the cover can be efficiently connected to the housing. Furthermore, a technical advantage can thereby be achieved that a secure and reliable connection is achieved between the cover and the housing. Due to the fact that the cover is formed from metal, a technical advantage is achieved, for example, that it is particularly stable. Due to the fact that the housing is formed from metal, a technical advantage is achieved, for example, that the housing is particularly stable.

This results in the technical advantage, for example, that the sensor can be produced efficiently. Furthermore, this results in the technical advantage, for example, that a robust and stable sensor is created.

Furthermore, a technical advantage may be achieved that positioning and alignment are simpler. Due to the fact that both parts are metallic and can be produced, for example, by turning, the positioning of the cover in or on the housing can be optimized in such a way that this can be carried out on the production line at strip level with normal picker tools rather than extra adjustment tools.

Furthermore, a technical advantage may be achieved that a cover can be manufactured and used for a specific housing, so that specific customer requirements can be addressed efficiently with regard to certain housing shapes.

Furthermore, a technical advantage may achieved that holes can be formed efficiently in a metallic cover by means of laser drilling in order to form, for example, a specific perforated grid with a certain hole size.

Furthermore, a technical advantage may be achieved that a tightness against liquids and dirt can be achieved. For this purpose, the cover can be welded in a circle and/or can also be used with a sealing ring if the corresponding trough is provided in the housing for this purpose.

Furthermore, a technical advantage may be achieved that better thermal properties can be achieved, which is advantageous for certain temperature trim flows.

Furthermore, a technical advantage may be achieved that better shielding against electromagnetic interference can be achieved.

Furthermore, a technical advantage may be achieved that fewer reliability problems can be caused during use, which can arise, for example, from the use of adhesives in polymer covers or from the use of polymer itself.

By fixing the cover to or in the housing opening, the housing opening is closed, so that in particular the sensor module is encapsulated. The method for producing a sensor can thus also be referred to as a method for encapsulating a sensor module. The method is used in particular in so-called “first-level packaging.”

In one embodiment of the method of the present invention, it is provided that the integral connection comprises laser welding by means of a welding laser.

This may result in a technical advantage, for example, that the integrally bonded connection can be formed efficiently.

According to an example embodiment of the present invention, it is thus provided that a laser welding process is carried out using a welding laser.

A wavelength of the laser light emitted by means of the welding laser is, for example, in the infrared range.

The welding laser is, for example, a Nd: YAG pulsed laser.

In one example embodiment of the method of the present invention, it is provided that welding regions are specified at which the cover is to be laser welded to the housing, wherein, based on the specified welding regions, a relative movement between the welding laser on the one hand and the cover and the housing on the other hand is controlled in such a way that the specified welding regions in each case reach the laser welding range of the welding laser, so that the welding laser welds the cover to the housing at the relevant welding region that has reached the laser welding range.

This may result in a technical advantage, for example, that the laser welding can be carried out efficiently. According to this embodiment, it is thus provided that the cover is welded to the housing at the welding regions.

For example, according to an example embodiment of the present invention, it is provided that the cover is welded to the housing exclusively at the specified welding regions. For example, it is provided that further welding regions at which the cover is welded to the housing are provided beyond the specified welding regions. For example, it is provided that the cover is welded to the housing over a complete circumference of the housing opening. This means, for example, that the welding regions in their entirety correspond to a complete circumference of the housing opening. The cover can thus, for example, be completely welded to the housing.

In one embodiment of the method of the present invention, it is provided that a shutter of the welding laser is controlled during the laser welding such that the shutter is opened only within the welding regions and otherwise is closed or is being closed.

This may result in a technical advantage, for example, that the laser welding can be carried out efficiently. According to this embodiment of the present invention, it is thus provided that laser radiation of the welding laser is emitted only within the welding regions, since the shutter is closed outside the welding regions. For example, a technical advantage can thus be achieved that the emission of potentially eye-damaging laser radiation can be reduced to a minimum.

A shutter within the meaning of the description can also be referred to as a closure.

In one example embodiment of the method of the present invention, it is provided that a virtual cross is specified on which the welding regions are located (or are arranged or aligned), wherein the relative movement is controlled based on the virtual cross such that the welding laser on the one hand and the cover and the housing on the other hand move relative to one another along the virtual cross, so that the welding regions each reach within the laser welding range.

This results in a technical advantage, for example, that the laser welding can be carried out efficiently.

According to this embodiment of the present invention, it is thus provided that the welding laser, for example, moves, in particular is steered, along the virtual cross, and/or that, for example, the cover and the housing move along the virtual cross as a common unit.

In one embodiment of the present invention, the welding laser is moved by means of a galvanometer scanner. The control of the relative movement comprises, for example, controlling the galvanometer scanner in such a way that, by moving the welding laser by means of the galvanometer scanner, the specified welding regions each pass into the laser welding range of the welding laser, so that the welding laser welds the cover to the housing at the relevant welding region that has reached the laser welding range. The control of the relative movement comprises, for example, controlling the galvanometer scanner based on the virtual cross in such a way that the welding laser on the one hand and the cover and the housing on the other hand move relative to one another along the virtual cross, so that the welding regions each reach within the laser welding range.

For example, according to an embodiment of the present invention, it is provided that the welding laser is controlled on the basis of the relative movement in such a way that the welding laser in each case approaches the predefined welding regions, so that the predefined welding regions each reach the laser welding range of the welding laser.

For example, according to an embodiment of the present invention, it is provided that the welding laser is controlled based on the virtual cross such that it travels along the virtual cross, so that the welding regions each reach within the laser welding range.

In one embodiment of the method of the present invention, it is provided that the welding laser is a picosecond laser, so that the laser welding is carried out by means of picosecond laser pulses.

This may result in a technical advantage, for example, that the laser welding can be carried out efficiently. For example, this may result in the technical advantage that there is little to no heat transfer to a protective medium located within the housing.

In one embodiment of the method of the present invention, it is provided that the welding laser is a nanosecond laser, so that the laser welding is carried out by means of nanosecond laser pulses.

This may result in a technical advantage, for example, that the laser welding can be carried out efficiently. For example, this may result in a technical advantage that there is little to no heat transfer to a protective medium located within the housing.

In one embodiment of the method of the present invention, it is provided that the welding laser is an impulse laser, so that the laser welding is carried out by means of laser pulses.

This may result in a technical advantage, for example, that the laser welding can be carried out efficiently. For example, this may result in a technical advantage that there is little to no heat transfer to a protective medium located within the housing.

A pulse duration of the laser pulses is, for example, in the microsecond range or in the nanosecond range or picosecond range.

In one embodiment of the method of the present invention, it is provided that a protective medium is poured into the housing after the sensor module is arranged in the housing. Such a protective medium is designed, for example, to transmit a property and/or a composition of an ambient medium of the sensor to the sensor module. A protective medium is, for example, or comprises, for example, a gel.

According to an example embodiment of the present invention, the sensor module is configured, for example, to detect a property and/or a composition of an ambient medium of the sensor.

The sensor is, for example, a pressure sensor. This means, for example, that the sensor module can detect a pressure.

The sensor module is designed, for example, as a micro-electromechanical system (MEMS).

According to an example embodiment of the present invention, the sensor module is arranged on an ASIC, for example. ASIC stands for “application specific integrated circuit,”

In one embodiment of the method of the present invention, it is provided that the housing opening is delimited by a receiving portion of the housing, wherein the receiving portion is formed in such a way that it receives the cover substantially without play, wherein the cover is arranged in the receiving portion in order to close the housing opening.

This may result in a technical advantage, for example, that the fixing can be carried out efficiently. According to this embodiment of the present invention, it is thus provided that the cover is arranged in the receiving portion. As a result, the cover is received by the receiving portion substantially without play. In this position, the cover can be efficiently integrally connected to the housing. In particular, laser welding can be efficiently performed in such a position. This is because, for example, the substantially play-free receiving achieves the technical advantage that a position of the cover relative to the housing substantially does not change, i.e., remains substantially constant, during the integral connecting, in particular during laser welding.

In one embodiment of the method of the present invention, the latter comprises a step of forming the receiving portion on the housing such that the housing opening is delimited by the receiving portion of the housing, wherein the receiving portion is formed in such a way that it receives the cover substantially without play,

The wording “substantially” is to be seen in connection with possible production tolerances. This means that “substantially without play” can mean that the cover is received without play in the receiving portion within the scope of manufacturing tolerances.

The wording “substantially without play” also includes the case in which the cover is received in the receiving portion without play.

In one embodiment of the method of the present invention, it is provided that this comprises a forming of the receiving portion on the housing.

This may result in a technical advantage, for example, that the receiving portion is formed so that the cover can be received in the receiving portion substantially without play.

In one embodiment of the method of the present invention, it is provided that the forming comprises milling the receiving portion from the housing.

This may result in a technical advantage, for example, that the receiving portion can be formed efficiently.

In one embodiment of the method of the present invention, it is provided that the housing comprises a sleeve within which the sensor module is arranged, and wherein the housing opening is an open side of the sleeve.

This may result in a technical advantage, for example, that the sensor module can be arranged efficiently.

In one embodiment of the method of the present invention, it is provided that this comprises a step of forming or producing a housing in such a way that the housing comprises a sleeve.

A sleeve within the meaning of the description herein denotes, for example, a tubular, elongate, solid sleeve. The sleeve is a metallic sleeve.

The sleeve has, for example, two opposite openings. This means in particular that a sleeve has opposite open sides. One of these sides or one of these openings of the sleeve forms the housing opening of the housing.

In one embodiment of the method of the present invention, it is provided that the receiving portion is formed on an end face of the open side of the sleeve.

This may result in a technical advantage, for example, that the receiving portion is formed or is being formed efficiently.

The sleeve comprises, for example, an open side which, for example, forms the housing opening. The receiving portion is formed, for example, on an end face of the open side or the sleeve. The receiving portion is milled, for example, from the end face. In this respect, the receiving portion has, for example, a stepped cross section. This means, for example, that a step was thereby milled into the end face, for example. For example, the metallic cover comprising a plurality of holes is arranged in this receiving portion.

For example, in an exemplary embodiment of the present invention, the dimensions of the cover and of the receiving portion are dimensioned such that the receiving portion, i.e., for example, the step, receives the cover substantially without play.

In one embodiment of the sensor of the present invention, it is provided that the cover is integrally connected to the housing by the cover being laser welded to the housing.

In one embodiment of the sensor of the present invention, it is provided that the cover is welded to the housing in welding regions.

In one embodiment of the sensor of the present invention, it is provided that the welding regions are located or arranged or aligned on a virtual cross.

In one embodiment of the sensor of the present invention, it is provided that the housing opening is delimited by a receiving portion of the housing, wherein the receiving portion is formed in such a way that it receives the cover substantially without play, wherein the cover is arranged in the receiving portion in order to close the housing opening.

In one embodiment of the sensor of the present invention, it is provided that the receiving portion is milled from the housing.

In one embodiment of the sensor of the present invention, it is provided that the housing comprises a sleeve within which the sensor module is arranged, and wherein the housing opening is an open side of the sleeve which is closed by means of the cover.

In one embodiment of the sensor of the present invention, it is provided that the receiving portion is formed on an end face of the open side of the sleeve.

In one embodiment of the sensor of the present invention, it is provided that it is produced by means of the method according to the first aspect.

Embodiments which are made in connection with the method according to the first aspect apply analogously to the sensor according to the second aspect and vice versa. This means, for example, that technical functionalities of the sensor result analogously from corresponding technical functionalities of the method and vice versa. Features of the sensor can thus be reflected in particular in corresponding method features and vice versa.

“Metallic” means, for example, that the corresponding article is formed from a metal or comprises one or more metals and/or comprises one or more metal alloys.

Preferred metals from which the cover, housing and/or sleeve can be formed comprise, for example, stainless steel.

In one embodiment of the method of the present invention, it is provided that the cover comprises one or more holes. Such a hole causes, for example, a connection between a housing interior and an environment of the sensor. For example, the technical advantage can thus be achieved that a property and/or a composition of an ambient medium of the sensor can be efficiently transmitted via the hole or the holes to the sensor module, in particular to the protective medium.

The integrally bonded connection comprises, for example, that the cover becomes integrally connected to the housing, i.e., over its entire circumference. A welding region thus runs, for example, over the entire circumference of the cover. Accordingly, for example, the cover is laser welded over the entire circumference of the cover.

The sensor is, for example, part of a sensor first-level package. This means that, for example, a sensor first-level package is disclosed which comprises the sensor.

In one embodiment of the method of the present invention, this comprises a step of forming a housing opening of the housing. This means, for example, that a housing opening is formed in or on the housing.

The present invention is explained in more detail below using preferred exemplary embodiments.

### BRIEF DESCRIPTION OF THE DRAWINGS

FIG. 1 shows a flow chart of a method for producing a sensor, according to an example embodiment of the present invention.

FIG. 2 shows a first sensor, according to an example embodiment of the present invention.

FIG. 3 shows a second sensor, according to an example embodiment of the present invention.

FIG. 4 shows a cross-sectional view of a sleeve of a third sensor, according to an example embodiment of the present invention.

FIG. 5 shows a plan view of the sleeve of FIG. 4, according to an example embodiment of the present invention.

FIG. 6 shows a fourth sensor, according to an example embodiment of the present invention.

FIG. 7 shows a fifth sensor, according to an example embodiment of the present invention.

FIG. 8 shows a sixth sensor, according to an example embodiment of the present invention.

### DETAILED DESCRIPTION OF EXAMPLE EMBODIMENTS

In the following, the same reference signs can be used for identical features.

FIG. 1 shows a flowchart of a method for producing a sensor, comprising the following steps:
arranging 101 a sensor module in a metallic housing, wherein the housing has a housing opening,
fixing 103 a metallic cover to or in the housing opening in order to close the housing opening by means of the cover,
wherein the fixing comprises an integral connecting 105 of the cover to the housing. The cover is thus integrally connected to the housing.

A sensor is thus produced which comprises a sensor module arranged in a metallic housing, wherein the housing has a housing opening, wherein the housing opening is closed by means of a metallic cover by the cover being integrally connected to the housing.

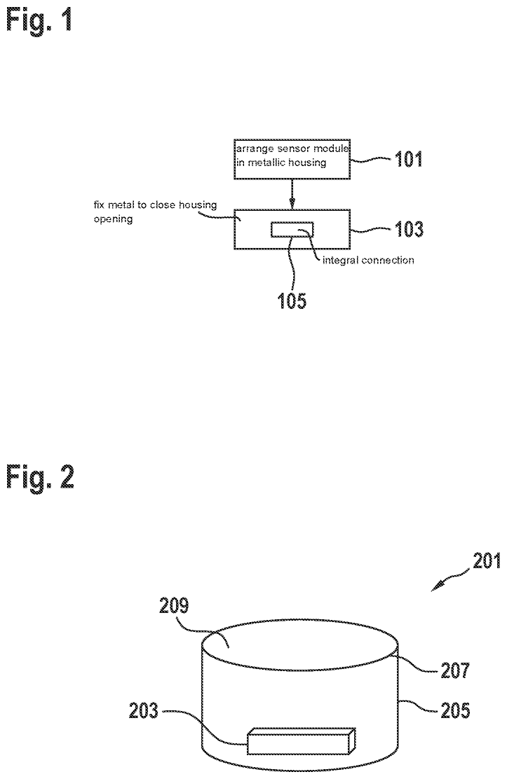

FIG. 2 shows a sensor 201 comprising:
a sensor module 203 arranged in a metallic housing, wherein the housing 205 has a housing opening 207,
wherein the housing opening 207 is closed by means of a metallic cover by the cover 209 being integrally connected to the housing.

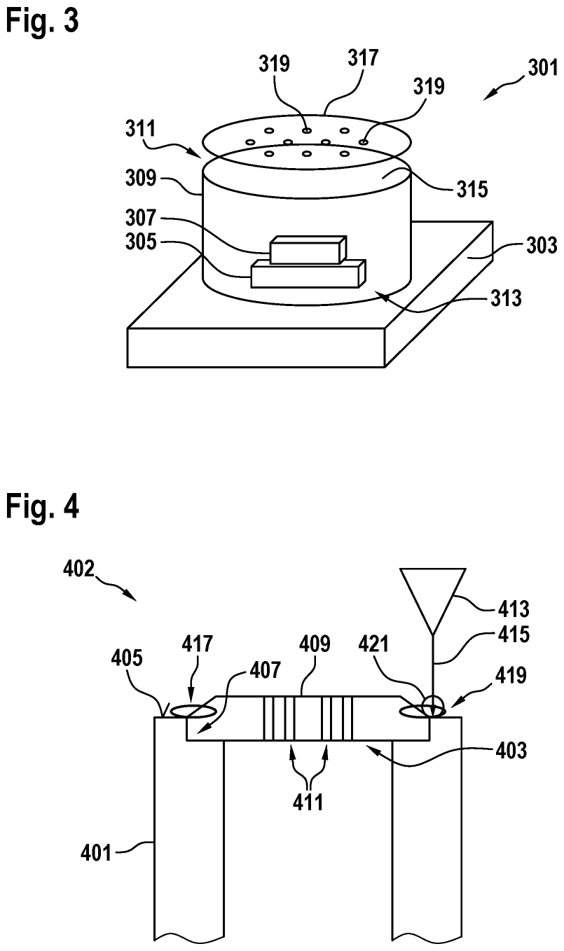

FIG. 3 shows a second sensor 301. The second sensor 301 comprises a substrate 303, for example a wafer. An ASIC 305 on which a sensor module 307 is arranged is arranged on the substrate 303. The user-specific integrated circuit 305 and the sensor module 307 are arranged within a housing 309 in the form of a sleeve.

The sleeve 309 has a first open side 311 and a second open side 313, which are formed opposite one another. A housing opening 315 of the housing 309 is thus formed on the first open side 311.

The second open side 313 is closed by means of the substrate 303.

The housing opening 315 is closed by means of a metallic cover 317 by the cover 317 being at least partially integrally connected to the sleeve 309, in particular laser welded.

The cover 317 has a plurality of holes 319, through which a connection is created or formed between the sleeve interior and an environment of the sensor 301.

For example, it is provided that the sensor module 307 is arranged in the sleeve 309 in that the sleeve 309 is arranged or placed on the substrate 303 with the second open side 313.

FIG. 4 shows a cross-sectional view of a metallic sleeve 401 of a third sensor 402, wherein only a partial view of the sensor 402 is shown for the sake of clarity. This means, for example, that the sensor module is not shown.

The sleeve 401 has an open side 403 which forms a housing opening. A receiving portion 407 is formed on an end face 405 of the open side 403 or of the sleeve 401. The receiving portion 407 was milled from the end face 405. In this respect, the receiving portion 407 has a stepped cross section. This means that a step was thereby milled into the end face 405. A metallic cover 409 comprising a plurality of holes 411 is arranged in said receiving portion 407. The dimensions of the cover 409 and of the receiving portion 407 are dimensioned such that the receiving portion 407, i.e., the step, receives the cover 409 substantially without play.

A welding laser 413 is also symbolically shown. The welding laser 413 emits laser radiation 415. A first welding region 417 and a second welding region 419 are specified, at which the welding laser 413 is to weld the cover 409 to the receiving portion 407, i.e., to the sleeve 401.

During laser welding by the welding laser 413, a plasma ball 421 is formed, with the use of which the cover 409 is welded to the sleeve 401.

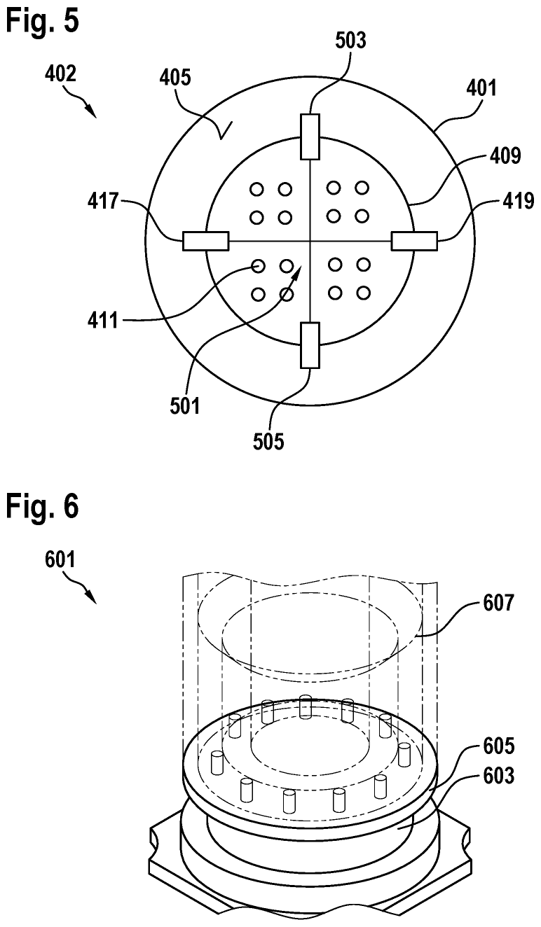

FIG. 5 shows a plan view of the third sensor 402 of FIG. 4, i.e., in particular a plan view of the cover 409 and of the sleeve 401.

According to FIG. 5, a virtual cross 501 is specified, wherein the two welding regions 417, 419 are located on the cross 501, more precisely at opposite ends of the cross 501. A third welding region 503 and a fourth welding region 505 are also specified, which are located at opposite further ends of the cross 501.

The laser welding is carried out, for example, in such a way that a shutter of the welding laser 413 is open only within the welding regions 417, 419, 503, 505, and the shutter is otherwise closed.

The welding laser 413 is, for example, a picosecond laser, thus emits laser pulses with a duration in the picosecond range.

The welding laser 413 moves, for example, along the virtual cross 501.

Using a picosecond laser, for example, the technical advantage is achieved that minimal heat transfer occurs by laser welding to the housing and/or to a protective medium present in the housing, for example a gel.

The provision of the receiving portion 407 achieves, for example, the technical advantage that the laser welding can be carried out without the cover 409 having to be held in position with separate fastening means. This is effected in particular by the receiving of the receiving portion 407 substantially without play.

FIG. 6 shows a fourth sensor 601 comprising a metallic housing 603, wherein the housing 603 comprises a housing opening which is closed by means of a metallic cover 605 by integral connecting of the cover 605 to the housing 603. Since FIG. 6 shows the cover 605 arranged on the housing opening, the housing opening is not shown since it is not visible.

Furthermore, a so-called picker 607 is shown, which can place the cover 605 on the housing 603, more precisely on the housing opening. A welding laser can then be used to weld the cover 605 with the housing 603 to one another.

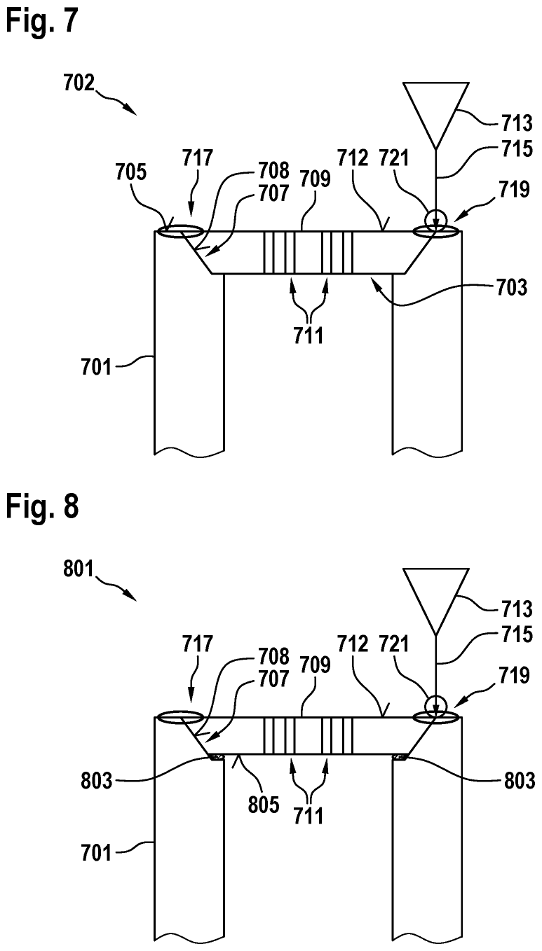

FIG. 7 shows a cross-sectional view of a metallic sleeve 701 of a fifth sensor 702, wherein only a partial view of the sensor 702 is shown for the sake of clarity. This means, for example, that the sensor module is not shown.

The sleeve 701 has an open side 703 which forms a housing opening. A receiving portion 707 is formed on an end face 705 of the open side 703 or of the sleeve 701. The receiving portion 707 was milled from the end face 705. In this respect, the receiving portion 707 has a stepped cross section. This means that a step was thereby milled into the end face 705. The step has an incline 708. In this respect, the step can be referred to as an inclined step. A metallic cover 709 comprising a plurality of holes 711 is arranged in this receiving portion 707. Here, the dimensions of the cover 709 and of the receiving portion 707 are measured such that the receiving portion 707, i.e., the step, receives the cover 709 substantially without play.

The end face 705 and an upper side 712 of the cover 709 form a common plane. This means that the upper side 712 with the end face 705 terminates the housing opening 703 in one plane, i.e., planarly.

A welding laser 713 is also shown symbolically. The welding laser 713 emits laser radiation 715. A first welding region 717 and a second welding region 719 are specified at which the welding laser 713 is to weld the cover 709 to the receiving portion 707 in each case, i.e. to the sleeve 701.

During laser welding by the welding laser 713, a plasma ball 721 is formed, with the use of which the cover 709 is welded to the sleeve 701.

FIG. 8 shows a cross-sectional view of a portion of a sixth sensor 801. The sensor 801 substantially corresponds to the fifth sensor 702 according to FIG. 7. Reference is made to the corresponding explanations to avoid repetitions.

A sealing ring 803 is provided as a differential. The sealing ring 803 is located between an underside 805 of the cover 709 and the receiving portion 707. A particularly good sealing effect is advantageously brought about by the sealing ring 83.

1-19. (canceled)

20. A method for producing a sensor, comprising the following steps:
arranging a sensor module in a metallic housing, wherein the housing has a housing opening; and
fixing a metallic coveron or in the housing opening to close the housing opening using the cover,
wherein the fixing includes an integral connecting of the cover to the housing.

21. The method according to claim 20, wherein the integrally connecting includes laser welding using a welding laser.

22. The method according to claim 21, wherein welding regions are specified at which the cover is to be laser welded to the housing, wherein, based on the specified welding regions, a relative movement between the welding laser on the one hand, and the cover and the housing on the other hand, is controlled in such a way that the specified welding regions each reach a laser welding range of the welding laser so that the welding laser welds the cover to the housing at the welding region that has reached the laser welding range.

23. The method according to claim 22, wherein a shutter of the welding laser is controlled during laser welding such that the shutter is opened only within the welding regions and is otherwise closed.

24. The method according to claim 22, wherein a virtual cross is specified on which the welding regions are located, wherein the relative movement is controlled based on the virtual cross such that the welding laseron the one hand, and the cover and the housing on the other hand move relative to one another along the virtual cross so that the welding regions each reach within the laser welding range.

25. The method according to claim 21, wherein the welding laser is a picosecond laser, so that the laser welding is performed using picosecond laser pulses.

26. The method according to claim 20, wherein the housing opening is delimited by a receiving portion of the housing, wherein the receiving portion is formed in such a way that it receives the cover substantially without play, wherein the cover is arranged in the receiving portion to close the housing opening.

27. The method according to claim 26, further comprising forming the receiving portion on the housing.

28. The method according to claim 27, wherein the forming includes milling the receiving portion from the housing.

29. The method according to claim 20, wherein the housing includes a sleeve within which the sensor module is arranged, and wherein the housing opening is an open side of the sleeve.

30. The method according to claim 29, wherein the housing opening is delimited by a receiving portion of the housing, wherein the receiving portion is formed in such a way that it receives the cover substantially without play, and wherein the cover is arranged in the receiving portion to close the housing opening, wherein the receiving portion is formed on an end face of the open side of the sleeve.

31. A sensor, comprising:
a sensor module which is arranged in a metallic housing, wherein the housing has a housing opening;
wherein the housing opening is closed using a metallic cover, the metallic cover being integrally connected to the housing.

32. The sensor according to claim 31, wherein the cover is integrally connected to the housing by the cover being laser welded to the housing.

33. The sensor according to claim 32, wherein the cover is welded to the housing on welding regions.

34. The sensor according to claim 33, wherein the welding regions are located on a virtual cross.

35. The sensor according to claim 31, wherein the housing opening is delimited by a receiving portion of the housing, wherein the receiving portion is formed such that it receives the cover substantially without play, wherein the cover is arranged in the receiving portion to close the housing opening.

36. The sensor according to claim 35, wherein the receiving portion is milled out of the housing.

37. The sensor according to claim 31, wherein the housing includes a sleeve within which the sensor module is arranged, and wherein the housing opening is an open side of the sleeve which is closed using the cover.

38. The sensor according to claim 37, wherein the housing opening is delimited by a receiving portion of the housing, wherein the receiving portion is formed such that it receives the cover substantially without play, wherein the cover is arranged in the receiving portion to close the housing opening, and wherein the receiving portion is formed on an end face of the open side of the sleeve.
